(19) United States
(12) Patent Application Publication
(10) Pub. No.: US 2023/0208378 A1
(43) Pub. Date: Jun. 29, 2023

(54) KHZ TO 100GHZ DC COUPLED CIRCUIT WITH AN ON-CHIP INTEGRATING CAPACITOR

(71) Applicant: SUZHOU MI TU OPTOELECTRONIC TECHNOLOGY CO. LTD., Suzhou (CN)

(72) Inventors: Zhi ZHANG, Suzhou (CN); Xianglin XIANG, Suzhou (CN)

(21) Appl. No.: 17/724,435

(22) Filed: Apr. 19, 2022

(30) Foreign Application Priority Data
Dec. 27, 2021 (CN) 202111610521.5

(51) Int. Cl. H03H 7/38; H03H 7/01

(52) U.S. Cl. CPC H03H 7/38; H03H 7/1783; H03H 2007/386

(57) ABSTRACT

A kHz to 100 GHz DC coupled circuit with an on-chip integrating capacitor includes an impedance matching structure, an input impedance, an input stage structure and an on-chip capacitor; the impedance matching structure comprises an matching inductor with one end connected to the input terminal and a first matching branch with one end connected to the input terminal, a second matching branch with one end connected to the other end of the matching inductor as well as the other end of the first matching branch, a third matching branch with one end connected to the matching inductor, in which the other ends of the second matching branch and the third matching branch are connected to the input impedance; the first, second and third matching branches are implemented as RLC circuits; or, one or two of the first, second, and third matching branches are break circuits, and the others are RLC circuits.

### FIELD OF THE DISCLOSURE

The disclosure relates to a kHz to 100 GHz DC coupled circuit with an on-chip integrating capacitor, which belongs to the electronic circuit technology.

### BACKGROUND

With the rapid development of optical communication technology, higher requirements such as wider bandwidth, higher integration level, lower power consumption and the like are put forward on high-speed electric chips.

The optical communication circuit and the conventional radio frequency circuit have many similarities, but there are essential differences: the requirements for the bandwidth are different. Conventional radio frequency circuits are narrowband systems, whereas optical communication circuits are broadband systems. Impedance matching is a key index in either optical communication circuit or conventional radio frequency circuit, and the effect of impedance matching directly affects the quality of signal transmission.

However, most radio frequency circuits require narrowband (e.g., GSM corresponds to an impedance matching with the center frequency of 900 MHz, and the frequency range of about 25 M, 3G corresponds to an impedance matching with the center frequency of 1800 MHz, and the frequency range of about 80 M), that is, the impedance matching of the radio frequency circuit is achieved around a specific center frequency (about 5%). In order to design an optical communication circuit, the corresponding impedance matching needs be implemented as broadband with a frequency range from 100 KHz to 100 GHz; therefore, the impedance matching design of a conventional radio frequency circuit circuit is not suitable for the broadband impedance matching design of electrical chip.

Meanwhile, a capacitor is needed to block the DC voltage inside and outside the chip, due to the inconsistence of the DC voltage inside and outside the chip. The traditional AC coupling solution is to add a broadband DC blocking capacitor outside the chip. However, AC coupling will cause the problem of large package size and low integration.

### SUMMARY

Provided is a kHz to 100 GHz DC coupled circuit with an on-chip integrating capacitor solving the problem of inability to achieve broadband impedance matching, which because the narrowband impedance matching design of the conventional radio frequency circuits is not suitable for the electronic chips who require a broadband impedance matching. Via the DC coupling scheme of integrating on-chip capacitor, it may reduce the package size and the cost, and improve the broadband impedance matching as well.

What the present disclosure provided is: a kHz to 100 GHz DC coupled circuit with an on-chip integrating capacitor, comprising: an impedance matching structure, an input impedance, an input stage structure and an on-chip capacitor; wherein the impedance matching structure is connected to the input stage structure through the on-chip capacitor, or, the on-chip capacitor is connected to the input stage structure through the impedance matching structure, and the input impedance is connected to the impedance matching structure.

The impedance matching structure comprises an matching inductor with one end connected to the input terminal and a first matching branch with one end connected to the input terminal, a second matching branch with one end connected to the other end of the matching inductor as well as the other end of the first matching branch, a third matching branch with one end connected to the matching inductor, in which the other end of the second matching branch and the other end of the third matching branch are connected to the input impedance.

The first matching branch, the second matching branch and the third matching branch are implemented as RLC circuits, the first matching branch, the second matching branch and the third matching branch include a same circuit structure or not; or, one or two of the first matching branch, the second matching branch and the third matching branch are break circuits, and the others are RLC circuits.

Optionally, the RLC is implemented as one of the following structures:
an inductor; or,
a capacitor; or,
a resistor; or,
an inductor and a capacitor connected in parallel; or,
an inductor and a resistor connected in parallel; or,
a capacitor and a resistor connected in parallel; or,
an inductor and a capacitor-resistor series structure connected in parallel; or,
a capacitor-resistor series structure and an inductor-resistor series structure connected in parallel; or,
a capacitor-resistor series structure and an inductor-capacitor series structure connected in parallel.

Optionally, the input stage structure comprises a current source, an input stage transistor connected to the current source; wherein the output terminal of the circuit is drawn between the input stage transistor and the current source.

Optionally, the input stage transistor is implemented as a CMOS or a bipolar transistor.

Optionally, the voltage input to the voltage input terminal of the input stage transistor is obtained by resistance voltage dividing; or, by multiplying the current by the resistance; or, output from a low dropout regulator.

Optionally, the matching inductor is implemented as a transmission line or an on-chip inductor.

Optionally, the circuit comprises two subsections arranged in a mirror image manner with each other, and each subsection comprises an impedance matching structure, an input impedance, an input stage structure and an on-chip capacitor.

Optionally, the input impedances in the two subsections are connected through a common mode filtering capacitor whose other end is grounded.

Optionally, the circuit described-above is integrated in one chip.

The benefits of the present disclosure may at least include: the kHz to 100 GHz DC coupled circuit with an on-chip integrating capacitor, comprises: an impedance matching structure, an input impedance, an input stage structure and an on-chip capacitor; the impedance matching structure comprises an matching inductor with one end connected to the input terminal, a first matching branch with one end connected to the input terminal, a second matching branch with one end connected to the other end of the matching inductor as well as the other end of the first matching branch, a third matching branch with one end connected to the matching inductor, in which the other end of the second matching branch and the other end of the third matching branch are connected to the input impedance; moreover, the first matching branch, the second matching branch and the third matching branch are implemented as RLC circuits, the first matching branch, the second matching branch and the third matching branch include a same circuit structure or not; or, one or two of the first matching branch, the second matching branch and the third matching branch are break circuits, and the others are RLC circuits. It may solve the problem of large package size and low integration of chips due to AC coupling; meanwhile, via the DC coupling scheme of integrating on-chip capacitors, it may save the large-size broadband capacitors on the PCB board, effectively reduce the package size of chips and the cost, and improve the continuity of the broadband impedance; additionally, the DC coupling could be achieved through the on-chip DC blocking capacitor C_dc, and the input return loss S11 of the chip could be reduced through the improved input matching network.

The foregoing explanation is only an overview of the technical scheme of this disclosure. In order to better understand the technical means of this disclosure and implement it in accordance with the content of the specification, the following is a better implementation example of this disclosure together with the attached drawings for detailed explanation.

### BRIEF DESCRIPTION OF THE DRAWINGS

FIG. 1 is a circuit diagram of the AC coupling scheme provided by an embodiment of this disclosure.

FIG. 2 is a schematic diagram of the kHz to 100 GHz DC coupled circuit with an on-chip integrating capacitor provided by an embodiment of this disclosure.

FIG. 3 is a schematic diagram of the different implementations of the RLC circuit provided by an embodiment of this disclosure.

FIG. 4 is a schematic diagram of different implementations of the input stage structure provided by an embodiment of this disclosure.

FIG. 5 is a schematic diagram of the kHz to 100 GHz DC coupled circuit with an on-chip integrating capacitor provided by an embodiment of this disclosure.

FIG. 6 is a schematic diagram of the kHz to 100 GHz DC coupled circuit with an on-chip integrating capacitor provided by another embodiment of this disclosure.

FIG. 7 is a schematic diagram of the input return loss S11 simulation results of the DC coupling scheme compared with the AC coupling scheme provided by an embodiment of this disclosure.

### DETAILED DESCRIPTION OF THE DISCLOSURE

Below are further described the specific implementation way of the present disclosure in conjunction with the drawings and examples. The following embodiments are used to clarify this disclosure but shall not limit the scope of this disclosure. The following embodiments are used to clarify this disclosure but shall not limit the scope of this disclosure.

Firstly, some terms involved in this disclosure are introduced below.

AC coupling consists of using a blocking capacitor to filter out the DC signal component from a signal with both AC and DC components.

DC coupling allows both AC and DC signals to pass through a connection; when using DC coupling, no additional blocking capacitor is added to filter the signal.

For example: if DC coupling is used to combine a 3 V DC level with 1 Vpp sine wave, the value of the output sine wave is 3 V±0.5 V, if AC coupling is used to combine a 3 V DC level with 1 Vpp sine wave, the value of the output sine wave is 0 V±0.5 V.

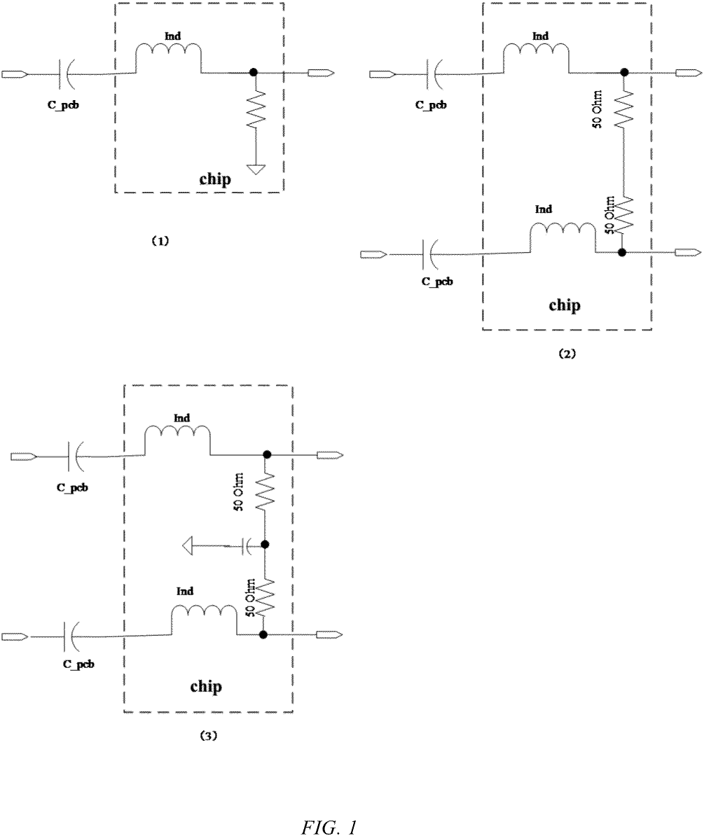

The conventional AC coupling structure for broadband chip is shown in FIG. 1, where C_pcb represents for PCB on-chip capacitor, Ind represents for inductor. According to the single-ended AC coupling structure of FIG. 1(1), and the differential AC coupling structures of FIG. 1(2) and FIG. 1(3), the C_pcb of each is set outside the chip for broadband DC blocking. However, it may lead to the problems of a large package size and a low integration level for chips.

Accordingly, the present disclosure provided a kHz to 100 GHz DC coupled circuit with an on-chip integrating capacitor to reduce the package size and the cost, and improve the impedance consistency of broadband system. The circuit of the present disclosure may be applied in wireless, microwave, base station, optical communication, signal interface between different analog modules, etc. The present embodiment is not meant to be a limitation of the application scenarios for the circuit of the present disclosure. The circuit is described below.

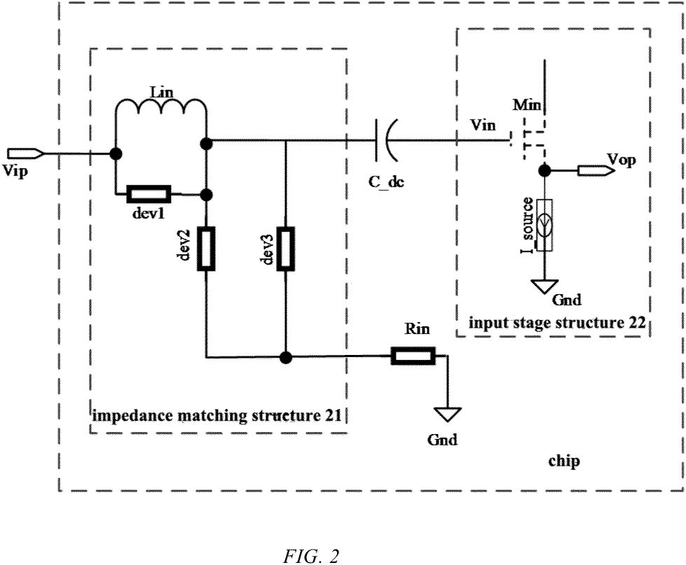

FIG. 2 is a schematic diagram of the kHz to 100 GHz DC coupled circuit with an on-chip integrating capacitor provided by an embodiment of this disclosure. As shown in FIG. 2, the circuit comprises: an impedance matching structure 21, an input impedance Rin, an input stage structure 22 and an on-chip capacitor C_dc.

The impedance matching structure 21 is connected to the input stage structure 22 through the on-chip capacitor, or, the on-chip capacitor is connected to the input stage structure 22 through the impedance matching structure 21, and the input impedance Rin is connected to the impedance matching structure 21.

In other words, the positions of the impedance matching structure 21 and the on-chip capacitor can be interchanged.

Referring to FIG. 2, the impedance matching structure 21 comprises an matching inductor Lin with one end connected to the input terminal Vip and a first matching branch dev1 with one end connected to the input terminal Vip, a second matching branch dev2 with one end connected to the other end of the matching inductor Lin as well as the other end of the first matching branch dev1, a third matching branch dev3 with one end connected to the matching inductor Lin, in which the other end of the second matching branch dev2 and the other end of the third matching branch dev3 are connected to the input impedance Rin.

The first matching branch dev1, the second matching branch dev2 and the third matching branch dev3 are implemented as RLC circuits, the first matching branch dev1, the second matching branch dev2 and the third matching branch dev3 include a same circuit structure or not.

Or, one or two of the first matching branch dev1, the second matching branch dev2 and the third matching branch dev3 are break circuits, and the others are RLC circuits. The circuit structure for the RLC-circuit matching branches may be the same or not. In other words, not all the first matching branch dev1, the second matching branch dev2 and the third matching branch dev3 are break circuits.

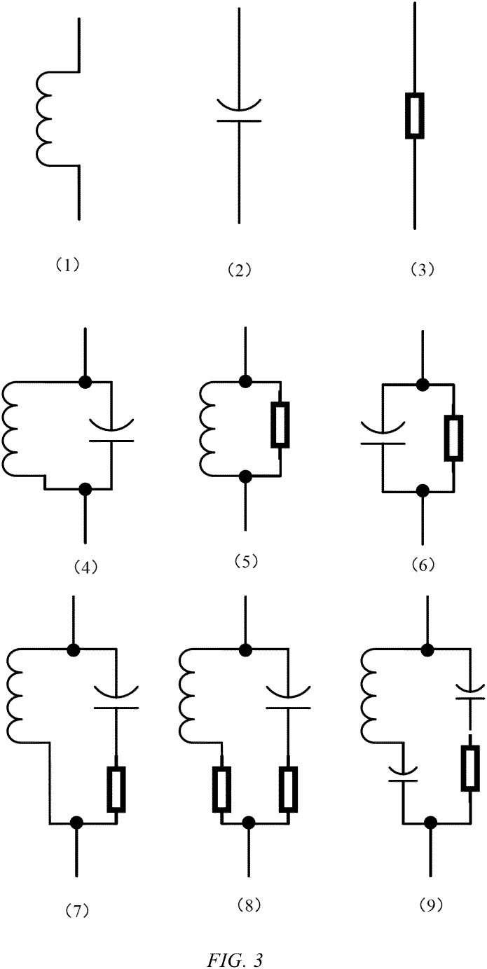

Referring to FIG. 3, the RLC is implemented as one of the following structures: an inductor shown in FIG. 3(1), or, a capacitor shown in FIG. 3(2); or, a resistor shown in FIG. 3(3); or, an inductor and a capacitor connected in parallel shown in FIG. 3(4); or, an inductor and a resistor connected in parallel shown in FIG. 3(5); or, a capacitor and a resistor connected in parallel shown in FIG. 3(6); or, an inductor and a capacitor-resistor series structure connected in parallel shown in FIG. 3(7); or, a capacitor-resistor series structure and a inductor-resistor series structure connected in parallel shown in FIG. 3(8); or, a capacitor-resistor series structure and a inductor-capacitor series structure connected in parallel shown in FIG. 3(9).

The input stage structure 22 comprises a current source I_source, an input stage transistor Min connected to the current source I_source; wherein the output terminal Vop of the circuit is drawn between the input stage transistor Min and the current source I_source.

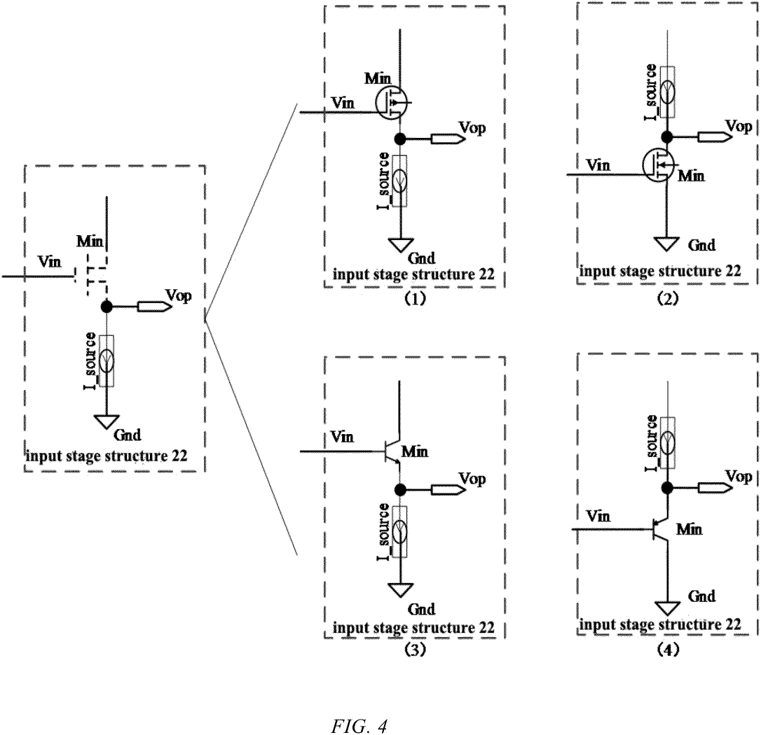

Exemplarily, the input stage transistor Min is implemented as a CMOS or a bipolar transistor. Referring to FIG. 4, as shown in FIG. 4(1), when the input stage transistor Min is implemented as a PMOS, the other end of the current source I_source is grounded. As shown in FIG. 4(2), when the input stage transistor Min is implemented as a NMOS, the other end of the NMOS is grounded. As shown in FIG. 4(3), when the input stage transistor Min is implemented as a NPN transistor, the other end of the current source I_source is grounded. As shown in FIG. 4(4), when the input stage transistor is implemented as a PNP transistor, the other end of the PNP transistor is grounded.

The voltage input to voltage input terminal Vin of the input stage transistor Min comprises the working DC voltage of the input stage transistor Min. Optionally, the voltage input to the voltage input terminal Vin is obtained by resistance voltage dividing; or, by multiplying the current by the resistance; or, output from a low dropout regulator.

Optionally, the matching inductor Lin may be implemented as a transmission line or an on-chip inductor.

Optionally, the impedance value of the input impedance Rin is typically 50 ohms. However, the impedance value of the input impedance Rin could also be adaptively set to other value upon the practical, the present embodiment is not meant to be a limitation of the impedance value for the input impedance Rin.

FIG. 1 takes single-ended DC coupling as an example for illustration, in which the other end of the input impedance Rin is grounded.

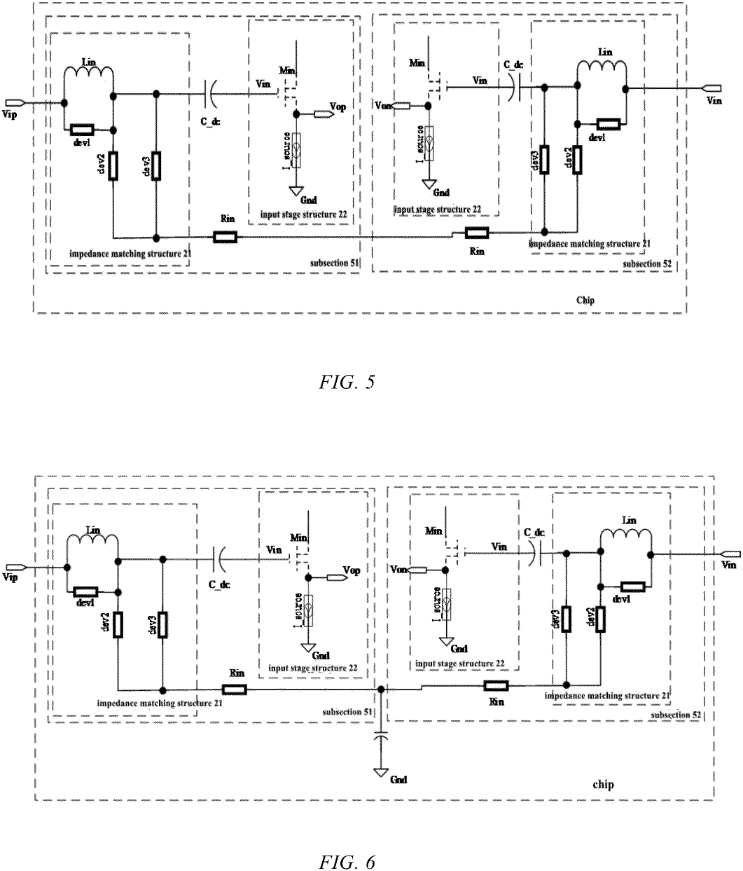

The circuit could also be implemented as differential DC coupling upon the practical. Specifically, referring to FIG. 5, the circuit comprises two subsections 51 and 52 arranged in a mirror image manner with each other, and each subsection comprises an impedance matching structure 21, an input impedance Rin, an input stage structure 22 and an on-chip capacitor. Additionally, the input impedances of the subsection 51 and 52 are connected.

Optionally, referring to FIG. 6, the input impedances Rin in the two subsections are connected; furthermore, the input impedances of the two subsections are connected to one end of a common mode filtering capacitor C_cm, and the other end of the common mode filtering capacitor C_cm is grounded.

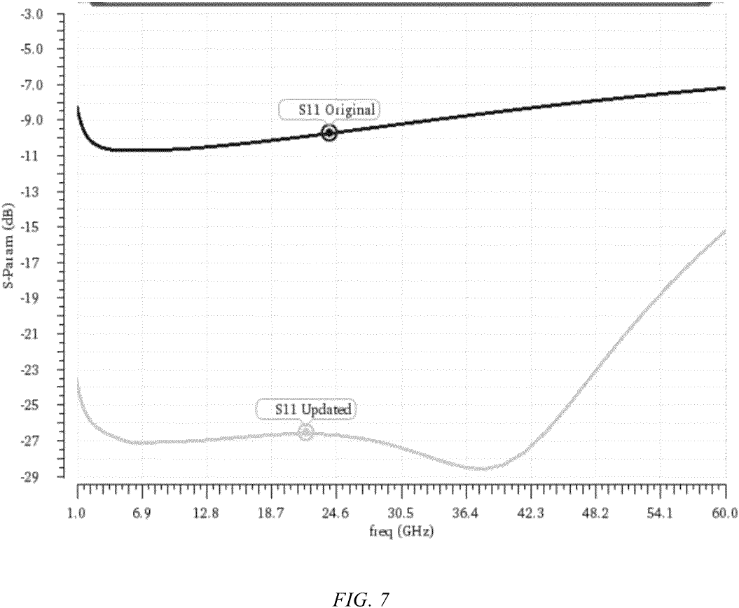

In the present embodiment, the above-mentioned circuits are integrated in one chip, thereby improving the integration of the chip and reducing the input return loss S11. FIG. 7, a schematic diagram of the input return loss S11 simulation results of the DC coupling scheme (a curve corresponding to S11 Updated in FIG. 7) compared with the AC coupling scheme (a curve corresponding to S11 Original in FIG. 7), that clearly illustrates the improved effect of the input return loss S11 for the DC coupling scheme provided by the present disclosures compared with the AC coupling scheme. Accordingly, the chip input return loss S11 is reduced by more than 17 dB, from 1.0 GHz to 60 GHz, thus the S11 value of the improved DC coupling scheme is significantly smaller than that of the AC coupling scheme.

In conclusion, provided kHz to 100 GHz DC coupled circuit with an on-chip integrating capacitor, comprising: an impedance matching structure 21, an input impedance Rin, an input stage structure and an on-chip capacitor. The impedance matching structure 21 comprises an matching inductor Lin with one end connected to the input terminal Vip and a first matching branch dev1 with one end connected to the input terminal Vip, a second matching branch dev2 with one end connected to the other end of the matching inductor Lin as well as the other end of the first matching branch dev1, a third matching branch dev3 with one end connected to the matching inductor Lin, in which the other end of the second matching branch dev2 and the other end of the third matching branch dev3 are connected to the input impedance Rin. The first matching branch dev1, the second matching branch dev2 and the third matching branch dev3 are implemented as RLC circuits, and the first matching branch dev1, the second matching branch dev2 and the third matching branch dev3 may include a same circuit structure or not; or, one or two of the first matching branch dev1, the second matching branch dev2 and the third matching branch dev3 are break circuits, and the others are RLC circuits. It may solve the problem of large package size and low integration of chips due to AC coupling; meanwhile, via the DC coupling scheme of integrating on-chip capacitors, it may save the large-size broadband capacitors on the PCB board, effectively reduce the package size of chips and the cost, and improve the continuity of the broadband impedance; additionally, the DC coupling could be achieved through the on-chip DC blocking capacitor C_dc, and the input return loss S11 of the chip could be reduced through the improved input matching network.

The technical features of the foregoing embodiments may be combined arbitrarily. For the sake of brevity, all possible combinations of the technical features of the foregoing embodiments are not described. However, as long as there is no contradiction in the combinations of these technical features, all shall be considered to be within the scope of this specification

The foregoing description has been made on several embodiments of this disclosure which are relatively specific and detailed, however the disclosure is not limited thereto. It should be further understood by those skilled in the art that various changes and modifications may be made without departing from the spirit of the disclosure are protected by this disclosure. Therefore, the scope of protection for this disclosure shall be subject to the appended claims.

1. A kHz to 100 GHz DC coupled circuit with an on-chip integrating capacitor, comprising:
an impedance matching structure, an input impedance, an input stage structure and an on-chip capacitor; wherein the impedance matching structure is connected to the input stage structure through the on-chip capacitor, or, the on-chip capacitor is connected to the input stage structure through the impedance matching structure, and the input impedance is connected to the impedance matching structure;
wherein, the impedance matching structure comprises an matching inductor with one end connected to the input terminal and a first matching branch with one end connected to the input terminal, a second matching branch with one end connected to the other end of the matching inductor as well as the other end of the first matching branch, a third matching branch with one end connected to the matching inductor, in which the other end of the second matching branch and the other end of the third matching branch are connected to the input impedance;
wherein the first matching branch, the second matching branch and the third matching branch are implemented as RLC circuits, the first matching branch, the second matching branch and the third matching branch include a same circuit structure or not; or, one or two of the first matching branch, the second matching branch and the third matching branch are break circuits, and the others are RLC circuits.

2. A kHz to 100 GHz DC coupled circuit with an on-chip integrating capacitor according to claim 1, wherein the RLC is implemented as one of the following structures:
an inductor; or,
a capacitor; or,
a resistor; or,
an inductor and a capacitor connected in parallel; or,
an inductor and a resistor connected in parallel; or,
a capacitor and a resistor connected in parallel; or,
an inductor and a capacitor-resistor series structure connected in parallel; or,
a capacitor-resistor series structure and an inductor-resistor series structure connected in parallel; or,
a capacitor-resistor series structure and an inductor-capacitor series structure connected in parallel.

3. A kHz to 100 GHz DC coupled circuit with an on-chip integrating capacitor according to claim 1, wherein the input stage structure comprises a current source, an input stage transistor connected to the current source; wherein the output terminal of the circuit is drawn between the input stage transistor and the current source.

4. A kHz to 100 GHz DC coupled circuit with an on-chip integrating capacitor according to claim 3, wherein the input stage transistor is implemented as a CMOS or a bipolar transistor.

5. A kHz to 100 GHz DC coupled circuit with an on-chip integrating capacitor according to claim 3, wherein the voltage input to the voltage input terminal of the input stage transistor is obtained by resistance voltage dividing; or, by multiplying the current by the resistance; or, output from a low dropout regulator.

6. A kHz to 100 GHz DC coupled circuit with an on-chip integrating capacitor according to claim 1, wherein the matching inductor is implemented as a transmission line or an on-chip inductor.

7. A kHz to 100 GHz DC coupled circuit with an on-chip integrating capacitor according to claim 1, wherein the circuit comprises two subsections arranged in a mirror image manner with each other, and each subsection comprises an impedance matching structure, an input impedance, an input stage structure and an on-chip capacitor.

8. A kHz to 100 GHz DC coupled circuit with an on-chip integrating capacitor according to claim 1, wherein the input impedances in the two subsections are connected through a common mode filtering capacitor whose other end is grounded.

9. A kHz to 100 GHz DC coupled circuit with an on-chip integrating capacitor according to claim 1, wherein the circuit is integrated in one chip.
